(19) United States
(12) Patent Application Publication
(10) Pub. No.: US 2006/0021734 A1
(43) Pub. Date: Feb. 2, 2006

(54) Heat sink and heat spreader bonding structure

(76) Inventors: Shih-Ying Chang, Banciao City (TW); Tung-Han Chuang, Taipei City (TW); Lan-Kai Yeh, Kaohsiung City (TW); Che-Wei Lin, Hsinchu City (TW); Ming-Jye Tsai, Sinpu Township (TW)

Correspondence Address: RABIN & BERDO, P.C., Suite 500, 1101 14 Street, N.W., Washington, DC, 20005, US

(21) Appl. No.: 10/999,928

(22) Filed: Dec. 1, 2004

(30) Foreign Application Priority Data
Jul. 30, 2004 (TW) 093122895

(51) Int. Cl. H05K 7/20

(52) U.S. Cl. 165/80.3; 361/704

(57) ABSTRACT

A heat sink and heat spreader bonding structure includes a metal heat sink, a metal heat spreader, and an eutectic structure formed between the heat sink and the heat spreader by heating the heat sink and the heat spreader to a specific temperature of the eutectic temperature of the heat sink and the heat spreader but below the respective melting point of the heat sink and the heat spreader to cause the internal metal atoms of the heat sink and heat spreader to be rearranged. This bonding structure maintains the heat transfer efficiency of the bonding layer between the heat sink and the heat spreader, eliminates formation of crevice, heat resistance, and oxidation in the bonding layer.

### BACKGROUND OF THE INVENTION

1. Field of the Invention

The present invention relates to a heat sink and heat spreader bonding structure and more particularly, to the bonding between different metal materials, for example, aluminum heat sink and copper heat spreader.

2. Description of Related Art

Following market tendency of electronic products toward high power, high function and high speed, the corresponding thermal generating is relatively increased. A raise in temperature may cause the electronic device, for example, CPU, to shorten its service life.

A heat dissipating device for electronic device is known comprising a copper heat spreader, and an aluminum heat sink bond to the copper heat spreader. The bonding layer between the copper heat spreader and the aluminum heat sink is decisive to heat dissipation efficiency. A poor bonded between the copper heat spreader and the aluminum heat sink may cause the heat energy generated by the electronic device to be accumulated in the bottom side of the heat sink. In this case, the electronic device may burn out due to overheat. Further, if there is a crevice in the bonding interface between the copper heat spreader and the aluminum heat sink, a great heat resistance will be produced, thereby lowering the heat dissipation efficiency.

In order to eliminate the aforesaid problems, thermal grease or thermally conductive tap may be used to seal interface crevices. However, because the heat transfer efficiency of thermal grease or thermally conductive tap is much lower than copper and aluminum, the bonding interface will affect the heat transfer efficiency of the aluminum heat sink and the copper heat spreader. Further, thermal grease or thermally conductive tap deteriorates after a long use.

Further, there is a design to have aluminum embedded in a copper plate by means of the characteristics that aluminum shrinks when cold and copper expands when hot. However, this design does not fill up crevices in the bonding interface with a heat conducting material, and heat resistance will be produced in the bonding interface. Further, because copper and aluminum have different coefficient of expansion, the crevices in the bonding interface between copper and aluminum expand after a long use of the electronic device, thereby lowering the heat dissipation efficiency.

Further, soldering technique is also commonly used to bond an aluminum heat sink to a copper heat spreader. However, the surface of aluminum and copper tends to be oxidized. The oxidized surface of the copper heat spreader and the aluminum heat sink will cause the soldered bonding interface to produce air holes or crevices, affecting heat transfer efficiency of the bonding interface between aluminum and copper.

### SUMMARY OF THE INVENTION

The present invention has been accomplished under the circumstances in view. It is therefore the main object of the present invention to provide a heat sink and heat spreader bonding structure that eliminates the aforesaid problems.

According to one embodiment of the present invention, the heat sink and heat spreader bonding structure comprises a heat sink, a heat spreader, and an intermediate element. The heat sink is made of a first metal material, which has a first melting point. The heat spreader is also made of the first metal material. The intermediate element is mounted in between the heat sink and the heat spreader and heated to a specific temperature to form a first bonding layer and a second bonding layer. The intermediate element comprises at least one outside area disposed in contact with the heat sink and the heat spreader respectively. The at least one outside area comprises at least a second metal material. The second metal material has a second melting point. The first metal material and the second metal material form eutectic structure when heated to above their eutectic temperature.

Further, the specific temperature is above the eutectic temperature of the first metal material and the second metal material but below the first melting point and the second melting point, such that the atoms of the first metal material of the heat sink and the atoms of the second metal material of the intermediate element are rearranged to construct an eutectic structure to form the first bonding layer, and the atoms of the first metal material of the heat spreader and the atoms of the second metal material of the intermediate element are rearranged to construct another eutectic structure to form the second bonding layer when heated to the specific temperature.

By means of the aforesaid eutectic bonding structure, the heat sink and the heat spreader are tightly joined together, maintaining the heat transfer efficiency of the bonding layer between the heat sink and the heat spreader. Therefore, this arrangement greatly improves heat dissipation efficiency, and eliminates the formation of crevice, heat resistance and oxidation in the bonding layer between the heat sink and the heat spreader.

The aforesaid first metal material can be copper. The intermediate element can be selected from a group of: an aluminum plate, an aluminum-copper eutectic foil, a copper plate peripherally coated with a layer of aluminum, a copper plate peripherally coated with a layer of aluminum-copper eutectic material, an aluminum plate peripherally coated with a layer of aluminum-copper eutectic material, a layer of aluminum coating directly coated on one of the heat sink and the heat spreader, and a layer of aluminum-copper eutectic material directly coated on one of the heat sink and the heat spreader. The coating can be respectively formed by means of one of the coating techniques including electroplating, evaporation, and sputtering.

Further, the first metal material can be aluminum, and the intermediate element can be selected from a group of: a copper plate, an aluminum-copper eutectic foil, an aluminum plate peripherally coated with a layer of copper, an aluminum plate peripherally coated with a layer of aluminum-copper eutectic material, a copper plate peripherally coated with a layer of aluminum-copper eutectic material, a layer of copper coating directly coated on one of the heat sink and the heat spreader, and a layer of aluminum-copper eutectic material directly coated on one of the heat sink and the heat spreader. The coating can be respectively formed by means of one of the coating techniques including electroplating, evaporation, and sputtering.

Further, the heat sink comprises a metal plate, which has a top surface and a bottom surface, and a plurality of upright radiation fins upwardly extended from the top surface of the metal plate of the heat sink. The heat spreader comprises a metal plate, which has a top surface. The first bonding layer and the second bonding layer are bonded between the bottom surface of the metal plate of the heat sink and the top surface of the metal plate of the heat spreader. At least one flange may be formed on at least one of the bottom surface of the metal plate of the heat sink and the top surface of the metal plate of the heat spreader around the border.

In an another form of the present invention, the heat sink comprises a plurality of radially extended radiation fins and a cylindrical center through hole, the heat spreader is a cylindrical member received in the cylindrical center through hole of the heat sink, and the first bonding layer and second bonding layer are bonded between the periphery of the cylindrical center through hole of the heat sink and the periphery of the cylindrical member of the heat spreader.

According to still another alternate form of the present invention, the heat sink and heat spreader bonding structure comprises a heat sink, a heat spreader, and an intermediate element. The heat sink is made of a first metal material, which has a first melting point. The heat spreader is made of a second metal material, which has a second melting point. The first metal material and the second metal material are different and capable of forming eutectic structure when heated to above their eutectic temperature.

The intermediate element is mounted in between the heat sink and the heat spreader and heated to a specific temperature to form a first bonding layer and a second bonding layer. The intermediate element comprises at least one top area and at least one bottom area, the at least one top area disposed in contact with the heat sink and comprises at least the second metal material, the at least one bottom area disposed in contact with the heat spreader and comprises at least the first metal material.

Further, the specific temperature is above the eutectic temperature of the first metal material and the second metal material but below the first melting point and the second melting point, such that the atoms of the first metal material of the heat sink and the atoms of the second metal material of the at least one top area of the intermediate element are rearranged to construct an eutectic structure and to form the first bonding layer, and the atoms of the second metal material of the heat spreader and the atoms of the first metal material of the at least one bottom area of the intermediate element are rearranged to construct another eutectic structure to form the second bonding layer when heated to the specific temperature.

By means of the bonding of the aforesaid eutectic structure, heat sink and heat spreader of same metal material or different metal materials are tightly bonded together.

The aforesaid first metal material and second metal material can be different and respectively selected from aluminum and copper. The intermediate element can be selected from a group of: a foil of the eutectic material of the first metal material and the second metal material, a bi-layer foil having a layer of the first metal material and a layer of the second metal material, a foil of the first metal material coated with a layer of the second metal material on the at least one top area thereof, a foil of the second metal material coated with a layer of the first metal material on the at least one bottom area thereof, a foil of the first metal material coated with a layer of eutectic material formed of the first metal material and the second metal material on the at least one top area thereof, a foil of the second metal material coated with a layer of eutectic material formed of the first metal material and the second metal material on the at least on bottom area thereof, and a layer of coating of eutectic material formed of the first metal material and the second metal material and directly coated on one of the heat sink and the heat spreader. Each of the aforesaid coatings can be respectively formed by means of one of the coating techniques including electroplating, evaporation, and sputtering.

Further, the aforesaid heat sink comprises a metal plate, which has a top surface and a bottom surface, and a plurality of upright radiation fins upwardly extended from the top surface of the metal plate of the heat sink. The heat spreader comprises a metal plate, which has a top surface. The first bonding layer and the second bonding layer are bonded between the bottom surface of the metal plate of the heat sink and the top surface of the metal plate of the heat spreader. Further, at least one flange is formed on at least one of the bottom surface of the metal plate of the heat sink and the top surface of the metal plate of the heat spreader around the border.

Alternatively, the heat sink can be made comprising a plurality of radially extended radiation fins and a cylindrical center through hole. In this case, the heat spreader is made in the form of a cylindrical member received in the cylindrical center through hole of the heat sink, and the first bonding layer and second bonding layer are bonded between the periphery of the cylindrical center through hole of the heat sink and the periphery of the cylindrical member of the heat spreader.

According to still another alternate form of the present invention, the heat sink and heat spreader bonding structure comprises a heat sink, a heat spreader, and a bonding layer. The heat sink is made of a first metal material, which has a first melting point. The heat spreader is made of a second metal material, which has a second melting point. The first metal material and the second metal material are different and capable of forming eutectic structure when heated to above their eutectic temperature. The bonding layer is formed in between the heat sink and the heat spreader upon heating of the heat sink and the heat spreader to a specific temperature. This specific temperature is above the eutectic temperature of the first metal material and the second metal material but below the first melting point and the second melting point, such that the atoms of the first metal material of the heat sink and the atoms of the second metal material of the heat spreader are rearranged to construct an eutectic structure to form the bonding layer when heated to the specific temperature.

By means of the bonding of the aforesaid eutectic structure, heat sink and heat spreader of same metal material or different metal materials are tightly bonded together.

The aforesaid first metal material and second metal material can be different and respectively selected from aluminum and copper.

Further, the heat sink comprises a metal plate, which has a top surface and a bottom surface, and a plurality of upright radiation fins upwardly extended from the top surface of the metal plate of the heat sink. The heat spreader comprises a metal plate, which has a top surface. The bonding layer is bonded between the bottom surface of the metal plate of the heat sink and the top surface of the metal plate of the heat spreader.

Alternatively, the heat sink can be made comprising a plurality of radially extended radiation fins and a cylindrical center through hole. In this case, the heat spreader is a cylindrical member received in the cylindrical center through hole of the heat sink, and the bonding layer is bonded between the periphery of the cylindrical center through hole of the heat sink and the periphery of the cylindrical member of the heat spreader.

### BRIEF DESCRIPTION OF THE DRAWINGS

FIG. 1 is an exploded view of the first embodiment of the present invention.

FIG. 2 is a sectional view of FIG. 1.

FIG. 3 illustrates an intermediate element according to the second embodiment of the present invention.

FIG. 4 illustrates an intermediate element according to the third embodiment of the present invention.

FIG. 5 illustrates an intermediate element according to the fourth embodiment of the present invention.

FIG. 6 illustrates an intermediate element according to the fifth embodiment of the present invention.

FIG. 7 is an elevational view of a part of the sixth embodiment of the present invention, showing the intermediate element bonded to the heat spreader.

FIG. 8 is an elevational view of a part of the seventh embodiment of the present invention, showing the intermediate element bonded to the heat spreader.

FIG. 9 is an exploded view of the eighth embodiment of the present invention.

FIG. 10 illustrates an intermediate element according to the ninth embodiment of the present invention.

FIG. 11 illustrates an intermediate element according to the tenth embodiment of the present invention.

FIG. 12 illustrates an intermediate element according to the 11^{th} embodiment of the present invention.

FIG. 13 illustrates an intermediate element according to the 12^{th} embodiment of the present invention.

FIG. 14 illustrates an intermediate element according to the 13^{th} embodiment of the present invention.

FIG. 15 illustrates an intermediate element according to the 14^{th} embodiment of the present invention.

FIG. 16 is an exploded view of the 15^{th} embodiment of the present invention.

FIG. 17 is an exploded view of the 16^{th} embodiment of the present invention.

FIG. 18 is a sectional view of the 16^{th} embodiment of the present invention, showing the first bonding layer and the second bonding layer bonded between the heat sink and the heat spreader.

FIG. 19 illustrates an intermediate element according to the 17^{th} embodiment of the present invention.

FIG. 20 illustrates an intermediate element according to the 18^{th} embodiment of the present invention.

FIG. 21 illustrates an intermediate element according to the 19^{th} embodiment of the present invention.

FIG. 22 illustrates an intermediate element according to the 20^{th} embodiment of the present invention.

FIG. 23 illustrates an intermediate element according to the 21^{st} embodiment of the present invention.

FIG. 24 is an elevational view of a part of the 22^{nd} embodiment of the present invention, showing the intermediate element bonded to the heat spreader.

FIG. 25 is an exploded view of the 23^{rd} embodiment of the present invention.

FIG. 26 is an exploded view of the 24^{th} embodiment of the present invention.

FIG. 27 is a sectional assembly view of FIG. 26.

FIG. 28 is an exploded view of the 25^{th} embodiment of the present invention.

### DETAILED DESCRIPTION OF THE PREFERRED EMBODIMENT

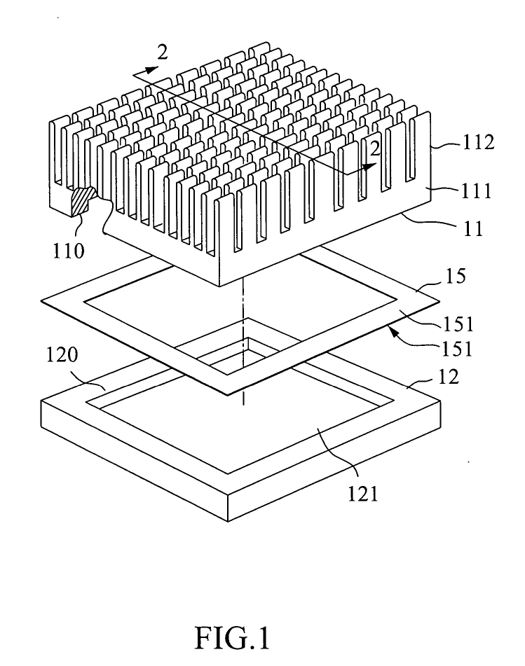

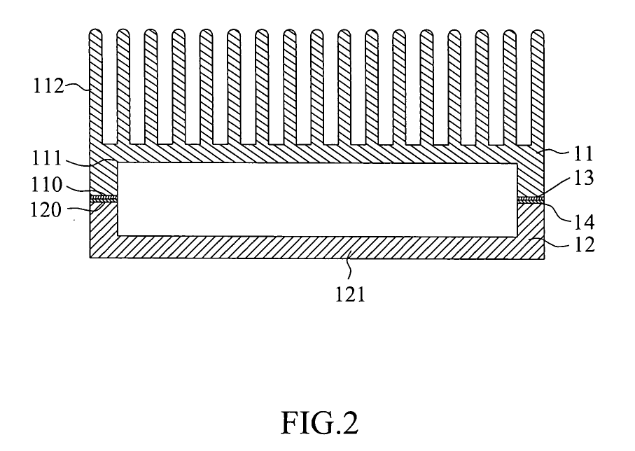

Referring to FIG. 1 and FIG. 2, a heat sink and heat spreader bonding structure in accordance with the first embodiment of the present invention is shown comprising a heat sink 11 and a heat spreader 12. The heat sink 11 is made of the copper of a first metal material, which has a first melting point t1. The head spreader 12 is also made of the copper of the first metal material.

This first embodiment also comprises a first bonding layer 13 and a second bonding layer 14. An intermediate element 15 is sandwiched in between the heat sink 11 and the heat spreader 12 and heated to a specific temperature t3, forming the first bonding layer 13 and the second bonding layer 14.

The aforesaid intermediate element 15 has an outside area 151 disposed in contact with the heat sink 11 and the heat spreader 12 respectively. The outside area 151 comprises a second metal material, which has a second melting point t2. According to this embodiment, the intermediate element 15 is an aluminum plate that forms with the copper heat sink 11 and copper heat spreader 12 a eutectic structure at above their eutectic temperature t4.

Further, the aforesaid specific temperature t3 is above the eutectic temperature t4 of copper and aluminum but below the first melting point t1 and the second melting point t2. Therefore, the first metal atoms of the copper heat sink 11 and the second metal atoms of the aluminum intermediate element 15 are rearranged to compose an eutectic structure, forming the first bonding layer 13. At the same time, the first metal atoms of the copper heat spreader 12 and the second metal atoms of the aluminum intermediate element 15 are rearranged to compose an eutectic structure, forming the second bonding layer 14.

According to this embodiment, the heat sink 11 comprises a metal plate 111 and a plurality of radiation fins 112 perpendicularly upwardly extended from the top surface of the metal plate 111. The heat spreader 12 comprises a metal plate 121. The first bonding layer 13 and the second bonding layer 14 are bonded between the bottom surface of the metal plate 111 of the heat sink 11 and the top surface of the metal plate 121 of the heat spreader 12. The metal plate 111 of the heat sink 11 has a flange 110 downwardly disposed at the bottom surface around the border. The metal plate 121 of the heat spreader 12 has a flange 120 upwardly disposed at the top surface around the border corresponding to the flange 110 of the metal plate 111 of the heat sink 11 for bonding.

The bonding of the aforesaid eutectic structure joins the copper heat sink 11 and the copper heat spreader 12 tightly and maintains the heat transfer efficiency of the first bonding layer 13 and the second bonding layer 14 between the heat sink 11 and the heat spreader 12, thereby improving heat dissipation efficiency and eliminating the problems of crevice, heat resistance and oxidation in the bonding layer as encountered in conventional designs.

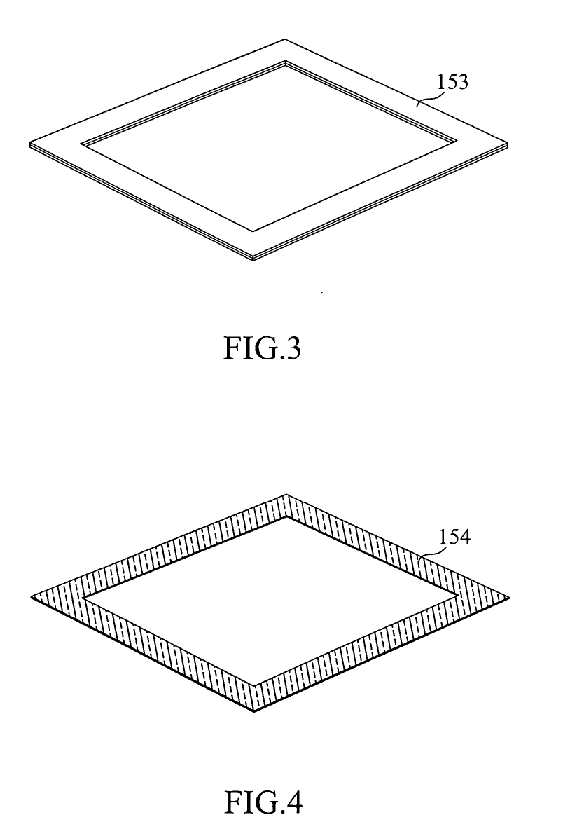

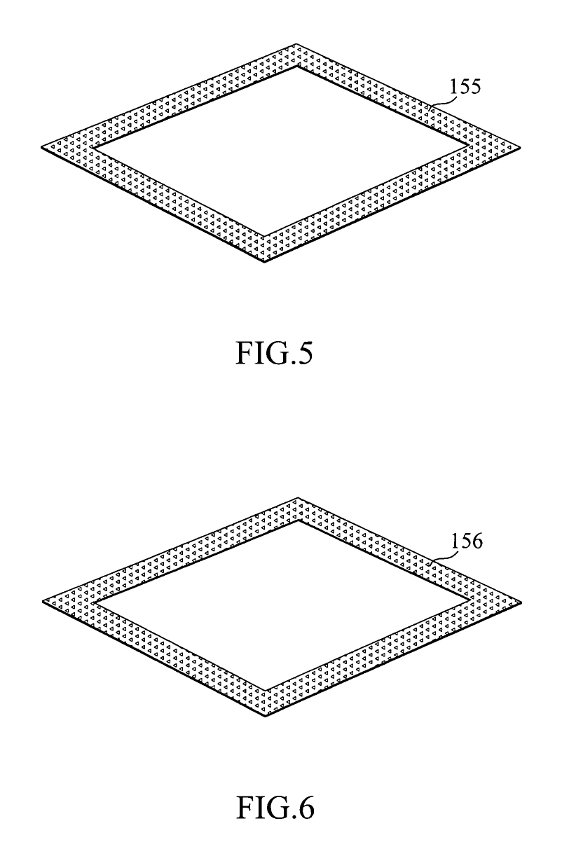

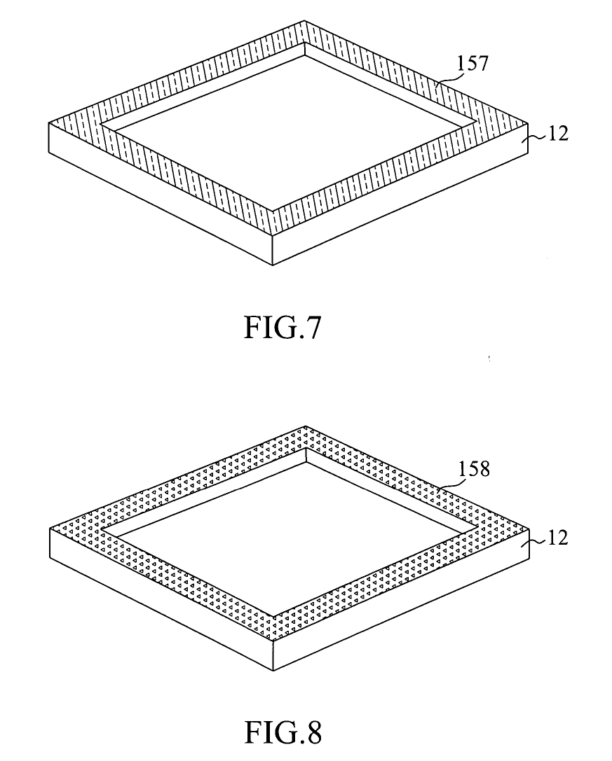

The aforesaid intermediate element 15 is not limited to use of an aluminum plate. According to the second embodiment of the present invention as shown in FIG. 3, the intermediate element 153 is an aluminum-copper eutectic foil. According to the third embodiment of the present invention as shown in FIG. 4, the intermediate element 154 is a copper plate peripherally coated with a layer of aluminum. According to the fourth embodiment of the present invention as shown in FIG. 5, the intermediate element 155 is a copper plate peripherally coated with a layer of aluminum-copper eutectic material. According to the fifth embodiment of the present invention as shown in FIG. 6, the intermediate element 156 is an aluminum plate peripherally coated with a layer of aluminum-copper eutectic material. According to the sixth embodiment of the present invention as shown in FIG. 7, the intermediate element 157 is a layer of aluminum coating directly coated on the heat spreader 12, of course it could directly coat on the heat spreader 11 (not shown). According to the seventh embodiment of the present invention as shown in FIG. 8, the intermediate element 158 is a layer of aluminum-copper eutectic material directly coated on the heat spreader 12, of course it could directly coat on the heat spreader 11 (not shown). Therefore, many options are available for the intermediate element 15. The formation of the layer of coating for the intermediate element can be achieved by any of a variety of conventional techniques including electroplating, evaporation, sputtering.

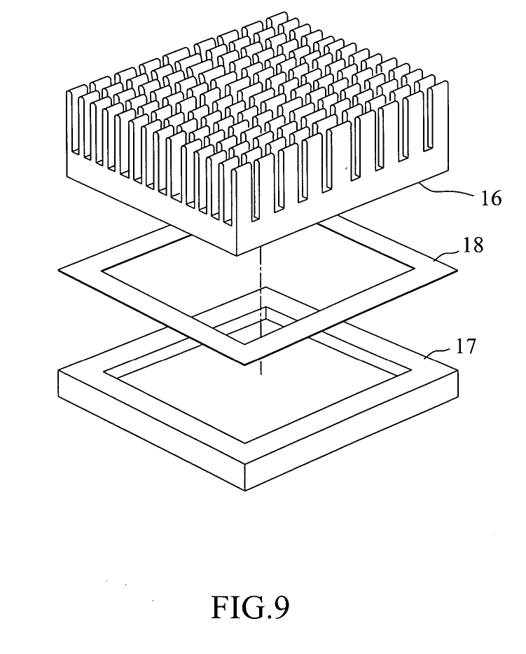

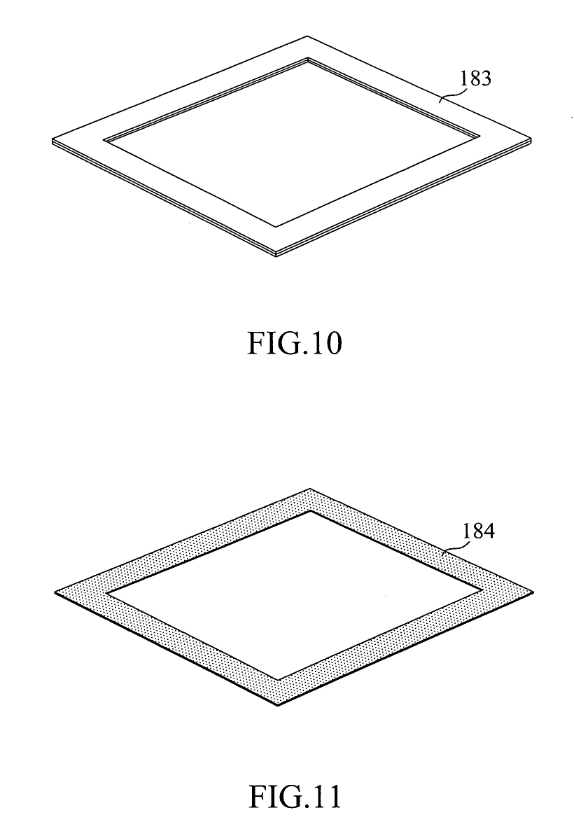

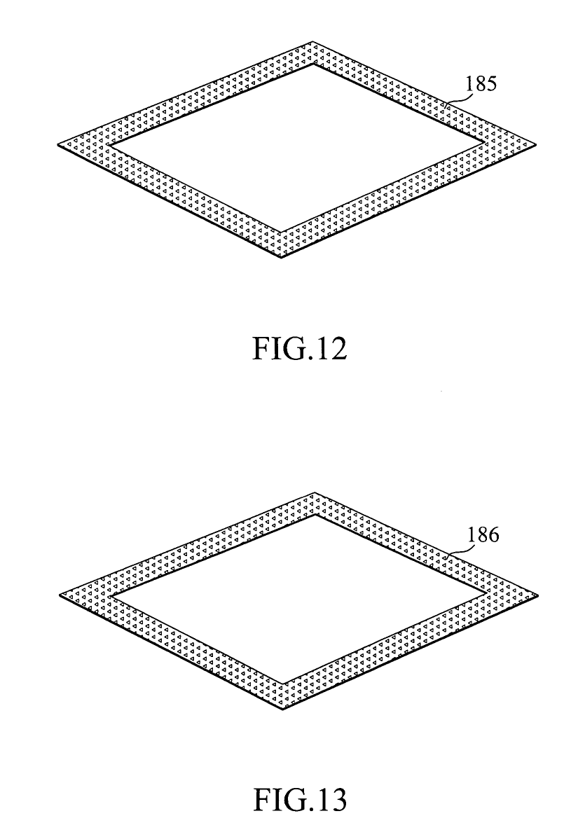

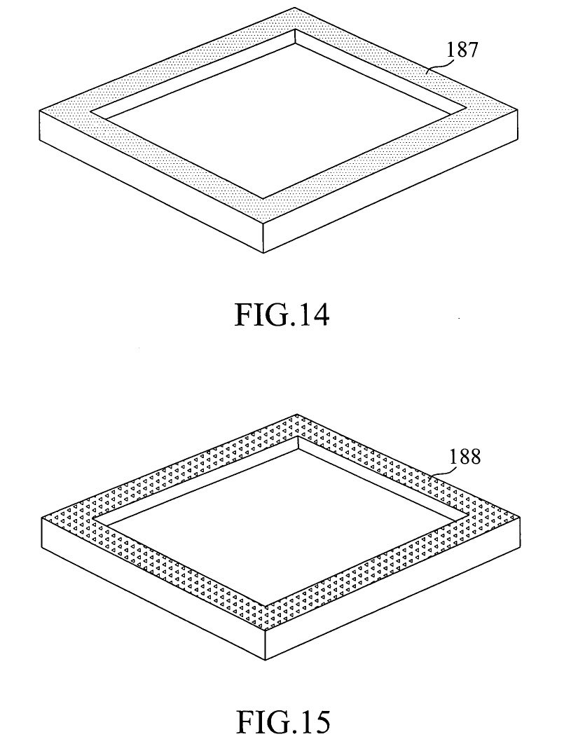

According to the aforesaid first embodiment of the present invention, the first metal material for the heat sink 11 and the heat spreader 12 is copper. According to the eighth embodiment of the present invention as shown in FIG. 9, the first metal material for the heat sink 16 and the heat spreader 17 is aluminum, and the second metal material for the intermediate element 18 is copper. The suitable metal material for the intermediate element 18 is not limited to copper. According to the ninth embodiment of the present invention as shown in FIG. 10, the intermediate element 183 is an aluminum-copper eutectic foil. According to the tenth embodiment of the present invention as shown in FIG. 11, the intermediate element 184 is an aluminum plate peripherally coated with a layer of copper. According to the eleventh embodiment of the present invention as shown in FIG. 12, the intermediate element 185 is an aluminum plate peripherally coated with a layer of aluminum-copper eutectic material. According to the twelfth embodiment of the present invention as shown in FIG. 13, the intermediate element 186 is a copper plate peripherally coated with a layer of aluminum-copper eutectic material. According to the thirteenth embodiment of the present invention as shown in FIG. 14, the intermediate element 187 is a layer of copper coating directly coated on the heat spreader 12, of course it could directly coat on the heat sink 11 (not shown). According to the fourteenth embodiment of the present invention as shown in FIG. 15, the intermediate element 188 is a layer of aluminum-copper eutectic material directly coated on the heat spreader 12, of course it could directly coat on the heat sink 11 (not shown). Therefore, many options are available for the intermediate element 18. The formation of the layer of coating for the intermediate element can be achieved by any of a variety of conventional techniques including electroplating, evaporation, sputtering.

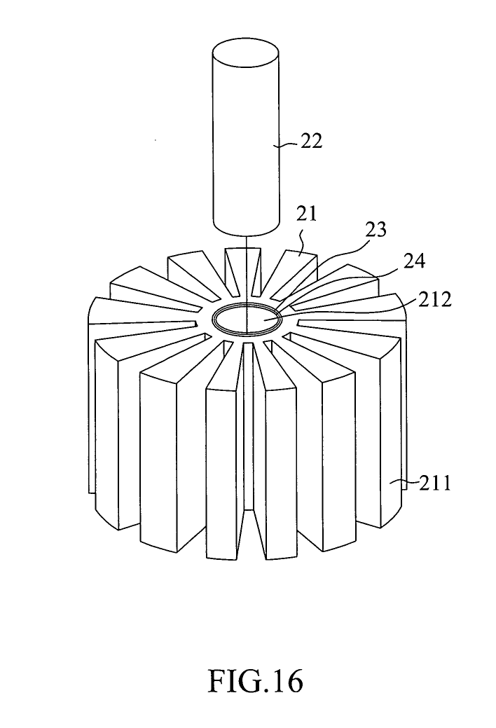

FIG. 16 is an exploded view of the fifteenth embodiment of the present invention. Similar to the aforesaid first embodiment of the present invention, this fifteenth embodiment comprises a heat sink 21 and a heat spreader 22. The heat sink 21 has a plurality of radially extended radiation fins 211 and a cylindrical center through hole 212. The heat spreader 22 is a cylindrical member received in the cylindrical center through hole 212 of the heat sink 21. The first bonding layer 23 and the second bonding layer 24 are bonded between the periphery of the cylindrical center through hole 212 of the heat sink 21 and the periphery of the cylindrical member of the heat spreader 22. This embodiment achieves the same effects as the aforesaid various embodiments of the present invention do.

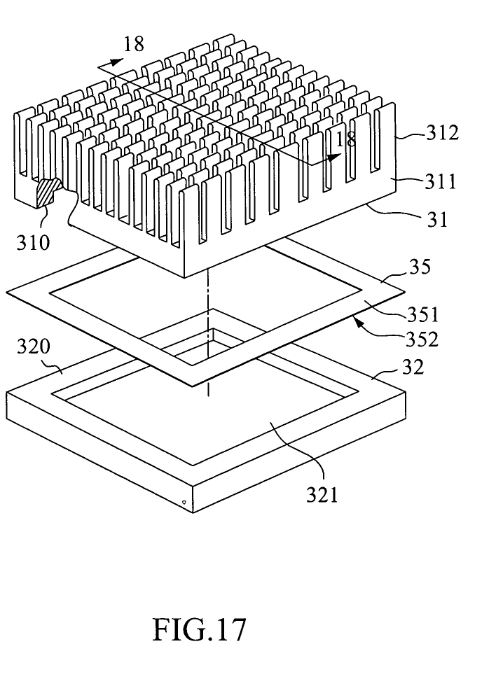

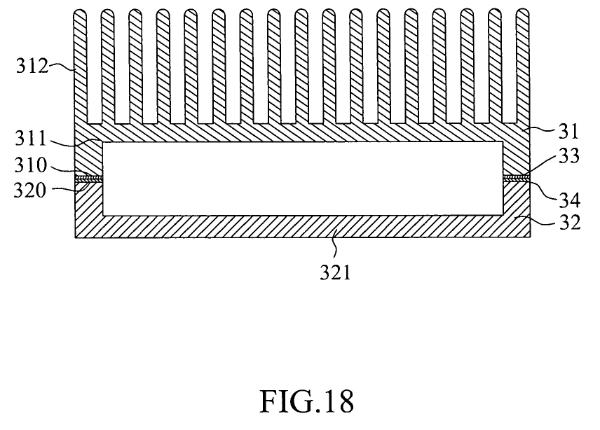

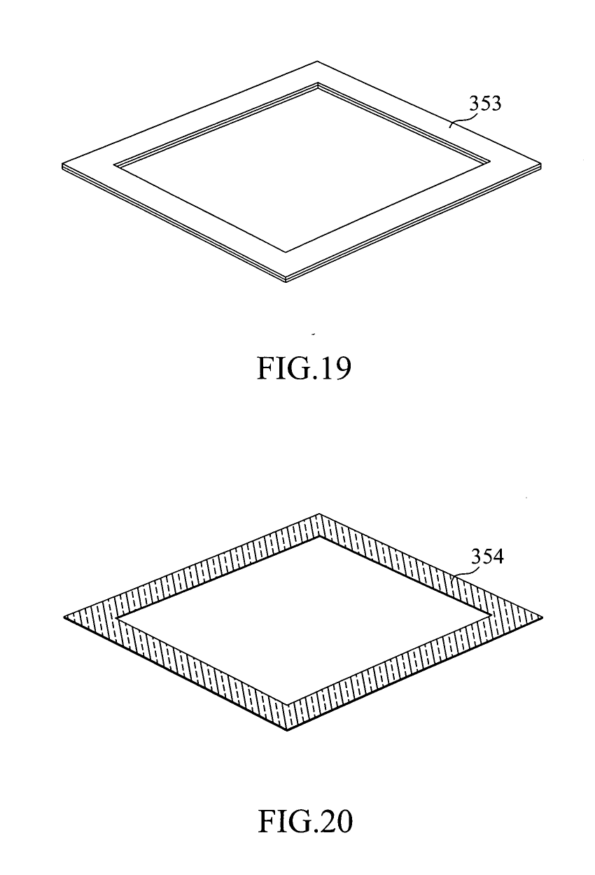

FIG. 17˜FIG. 19 shows a heat sink and heat spreader bonding structure according to the sixteenth embodiment of the present invention. According to this embodiment, the heat sink and heat spreader bonding structure comprises a heat sink 31, a heat spreader 32, a first bonding layer 33, and a second bonding layer 34. The heat sink 31 is made of a first metal material having a first melting point T1. The heat spreader 32 is made of a second metal material having a second melting point T2. The first metal material and the second metal material are different, and can form eutectic structure at above their eutectic temperature T4.

An intermediate element 35 is sandwiched in between the heat sink 31 and the heat spreader 32 and heated to a specific temperature T3, forming the first bonding layer 33 and the second bonding layer 34.

The aforesaid intermediate element 35 has a top area 351, which is disposed in contact with the heat sink 31 and contains a second metal material, and a bottom area 352, which is disposed in contact with the heat spreader 32 and contains a first metal material. According to this embodiment, the first metal material and the second metal material are aluminum and copper, and the intermediate element 35 is made of an eutectic material of the first metal material and the second metal material.

Further, the aforesaid specific temperature T3 is above the eutectic temperature T4 of the first and second metal materials but below the first melting point T1 and the second melting point T2. Therefore, the first metal atoms of the aluminum heat sink 31 and the second metal atoms of the top area 351 of the intermediate element 35 are rearranged to compose an eutectic structure, forming the first bonding layer 33. At the same time, the second metal atoms of the copper heat spreader 32 and the first metal atoms of the bottom area 352 of the intermediate element 35 are rearranged to compose eutectic structure, forming the second bonding layer 34.

According to this embodiment, the heat sink 31 comprises a metal plate 311 and a plurality of radiation fins 312 perpendicularly upwardly extended from the top surface of the metal plate 311. The heat spreader 32 comprises a metal plate 321. The first bonding layer 33 and the second bonding layer 34 are bonded between the bottom surface of the metal plate 311 of the heat sink 31 and the top surface of the metal plate 321 of the heat spreader 32. The metal plate 311 of the heat sink 31 has a flange 310 downwardly disposed at the bottom surface around the border. The heat spreader 32 has a flange 320 upwardly disposed at the top surface around the border corresponding to the flange 310 of the metal plate 311 of the heat sink 31 for bonding.

The bonding of the eutectic structure joins the aluminum heat sink 31 and the copper heat spreader 32 tightly and maintains the heat transfer efficiency of the first bonding layer 33 and the second bonding layer 34 between the heat sink 31 and the heat spreader 32, thereby improving heat dissipation efficiency effectively.

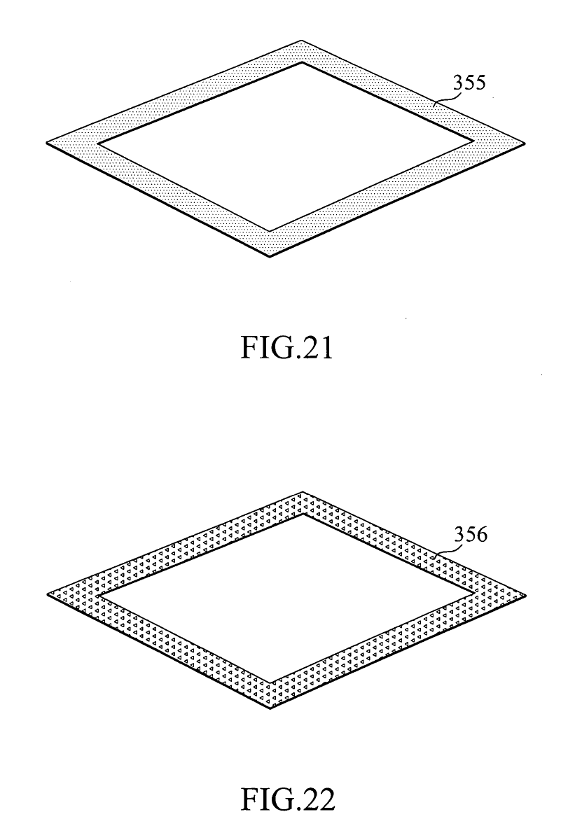

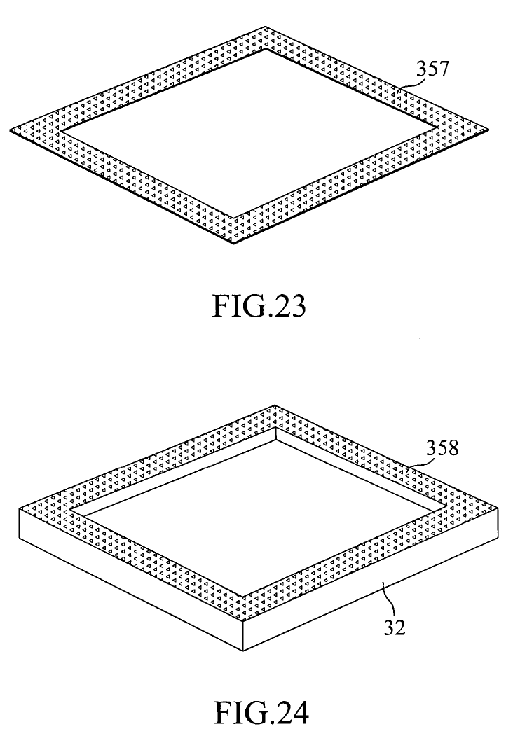

The aforesaid intermediate element 35 is not limited to use of an eutectic foil of the aforesaid first metal material and second metal material. According to the seventeenth embodiment of the present invention as shown in FIG. 19, the intermediate element 353 is a bi-layer foil having a layer of first metal material and a layer of second metal material. According to the eighteenth embodiment of the present invention as shown in FIG. 20, the intermediate element 354 is a foil of the first metal material coated with a layer of second metal material on the top area thereof. According to the nineteenth embodiment of the present invention as shown in FIG. 21, the intermediate element 355 is a foil of the second metal material coated with a layer of first metal material on the bottom area thereof. According to the twentieth embodiment of the present invention as shown in FIG. 22, the intermediate element 356 is a foil of the first metal material coated with a layer of eutectic material formed of the aforesaid first metal material and second metal material on the top area thereof. According to the 21^{st} embodiment of the present invention as shown in FIG. 23, the intermediate element 357 is a foil of the second metal material coated with a layer of eutectic material formed of the aforesaid first metal material and second metal material on the bottom area thereof. According to the 22^{nd} embodiment of the present invention as shown in FIG. 24, the intermediate element 358 is a layer of coating of eutectic metal material of the aforesaid first metal material and second metal material directly coated on the heat sink 32, of course it could directly coat on the heat spreader 31 (not shown). Therefore, different options are available for the intermediate element 35. With respect to the formation of the coating, it can be achieved by conventional techniques including electroplating, evaporation, and sputtering

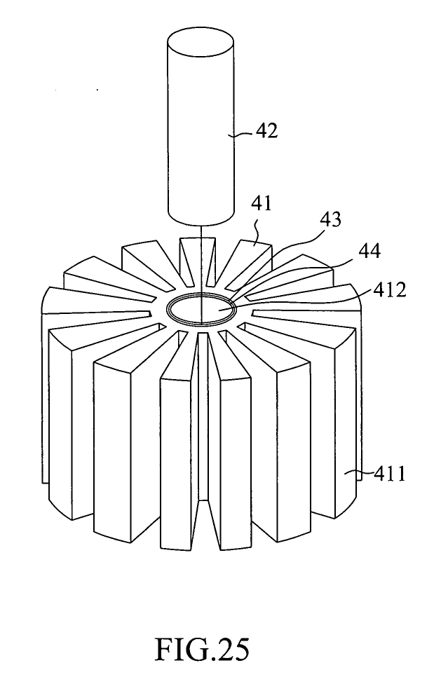

FIG. 25 is an exploded view of the 23^{rd} embodiment of the present invention. This essential structure of this embodiment is same as the aforesaid 16^{th} embodiment. Similar to the aforesaid 16^{th} embodiment of the present invention, this 23^{rd} embodiment comprises a heat sink 41 and a heat spreader 42. The heat sink 41 has a plurality of radially extended radiation fins 411 and a cylindrical center through hole 412. The heat spreader 42 is a cylindrical member received in the cylindrical center through hole 412 of the heat sink 41. The first bonding layer 43 and the second bonding layer 44 are bonded between the periphery of the cylindrical center through hole 412 of the heat sink 41 and the periphery of the cylindrical member of the heat spreader 42. This embodiment achieves the same effects as the aforesaid various embodiments of the present invention do.

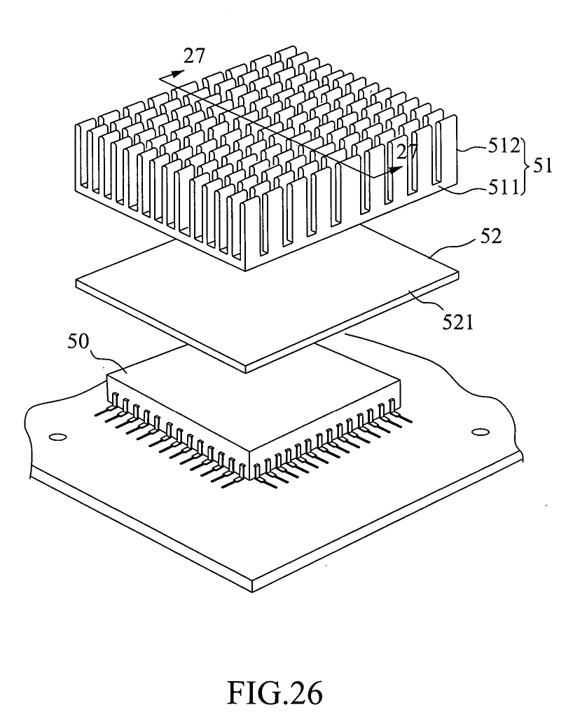

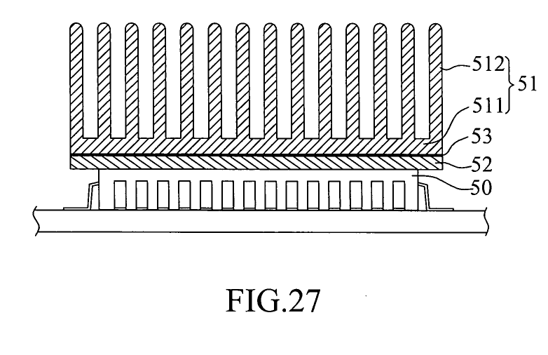

FIG. 26 and FIG. 27 show a heat sink and heat spreader bonding structure according to the 24^{th} embodiment of the present invention. According to this embodiment, the heat sink and heat spreader bonding structure comprises a heat sink 51, a heat spreader 52, and a bonding layer 53. When bonded together, the heat sink and heat spreader bonding structure is attached to an electronic thermal device, for example, CPU 50. The heat sink 51 is made of a first metal material having a first melting point T5. The heat spreader 52 is made of a second metal material having a second melting point T6. The first metal material and the second metal material are different, and can form eutectic structure at above their eutectic temperature T8. According to this embodiment, the first metal material and the second metal material are aluminum and copper respectively.

Further, the bonding layer 53 is formed between the heat sink 51 and the heat spreader 52 when the heat sink 51 and the heat spreader 52 were heated to a specific temperature T7. This specific temperature T7 is above the eutectic temperature T8 of the first metal material and the second metal material but below the first melting point T5 and the second melting point T6, causing the first metal atoms of the aluminum heat sink 51 and the second metal atoms of the copper heat spreader 52 to construct an eutectic structure and to form the bonding layer 53.

According to this embodiment, the heat sink 51 comprises a metal plate 511 and a plurality of upright radiation fins 512 upwardly extended from the top surface of the metal plate 511 of the heat sink 51; the heat spreader 52 comprises a metal plate 521; the bonding layer 53 is bonded between the bottom surface of the metal plate 511 of the heat sink 51 and the top surface of the metal plate 521 of the heat spreader 52.

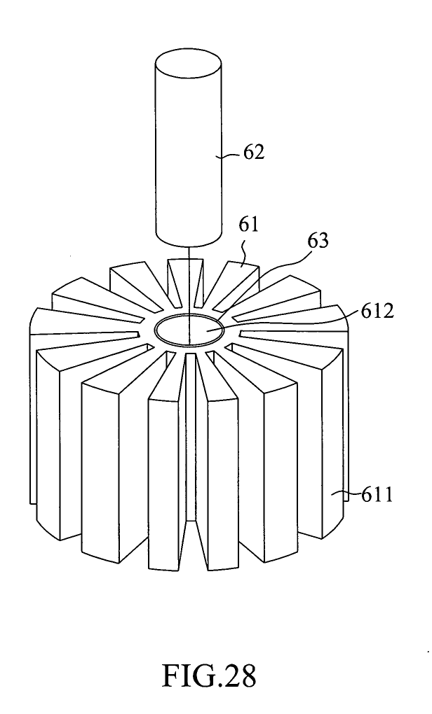

FIG. 28 is an exploded view of the 25^{th} embodiment of the present invention. The essential structure of this embodiment is same as the aforesaid 24^{th} embodiment with the exception that the heat sink 61 of the 25^{th} embodiment comprises a plurality of radially extended radiation fins 611 and a cylindrical center through hole 612; the heat spreader 62 of the 25^{th} embodiment is a cylindrical member received in the cylindrical center through hole 612 of the heat sink 61; the bonding layer 63 is bonded between the periphery of the cylindrical center through hole 612 of the heat sink 61 and the periphery of the cylindrical member of the heat spreader 62. This embodiment achieves the same effects as the aforesaid 16^{th} embodiment does.

Although the present invention has been explained in relation to its preferred embodiments, it is to be understood that many other possible modifications and variations can be made without departing from the spirit and scope of the invention as hereinafter claimed.

What is claimed is:

1. A heat sink and heat spreader bonding structure comprising:
a heat sink made of a first metal material, said first metal material having a first melting point;
a heat spreader made of said first metal material; and
an intermediate element mounted in between said heat sink and said heat spreader and heated to a specific temperature to form a first bonding layer and a second bonding layer;
wherein said intermediate element comprises at least one outside area disposed in contact with said heat sink and said heat spreader respectively, said at least one outside area comprising at least a second metal material, said second metal material having a second melting point, said first metal material and said second metal material forming an eutectic structure when heated to above their eutectic temperature;
wherein said specific temperature is above the eutectic temperature of said first metal material and said second metal material but below said first melting point and said second melting point, such that the atoms of the first metal material of said heat sink and the atoms of the second metal material of said intermediate element are rearranged to construct an eutectic structure to form said first bonding layer, and the atoms of the first metal material of said heat spreader and the atoms of the second metal material of said intermediate element are rearranged to construct another eutectic structure to form said second bonding layer when heated to said specific temperature.

2. The heat sink and heat spreader bonding structure as claimed in claim 1, wherein said first metal material is copper; said intermediate element is selected from a group of: an aluminum plate, an aluminum-copper eutectic foil, a copper plate peripherally coated with a layer of aluminum, a copper plate peripherally coated with a layer of aluminum-copper eutectic material, an aluminum plate peripherally coated with a layer of aluminum-copper eutectic material, a layer of aluminum coating directly coated on one of said heat sink and said heat spreader, and a layer of aluminum-copper eutectic material directly coated on one of said heat sink and said heat spreader.

3. The heat sink and heat spreader bonding structure as claimed in claim 2, wherein each said coating is respectively formed by means of one of the coating techniques including electroplating, evaporation, and sputtering.

4. The heat sink and heat spreader bonding structure as claimed in claim 1, wherein said first metal material is aluminum; said intermediate element is selected from a group of: a copper plate, an aluminum-copper eutectic foil, an aluminum plate peripherally coated with a layer of copper, an aluminum plate peripherally coated with a layer of aluminum-copper eutectic material, a copper plate peripherally coated with a layer of aluminum-copper eutectic material, a layer of copper coating directly coated on one of said heat sink and said heat spreader, and a layer of aluminum-copper eutectic material directly coated on one of said heat sink and said heat spreader.

5. The heat sink and heat spreader bonding structure as claimed in claim 4, wherein each said coating is respectively formed by means of one of the coating techniques including electroplating, evaporation, and sputtering.

6. The heat sink and heat spreader bonding structure as claimed in claim 1, wherein said heat sink comprises a metal plate, which has a top surface and a bottom surface, and a plurality of upright radiation fins upwardly extended from the top surface of the metal plate of said heat sink; said heat spreader comprises a metal plate, which has a top surface; said first bonding layer and said second bonding layer are bonded between the bottom surface of the metal plate of said heat sink and the top surface of the metal plate of said heat spreader.

7. The heat sink and heat spreader bonding structure as claimed in claim 6, wherein at least one flange is formed on at least one of the bottom surface of the metal plate of said heat sink and the top surface of the metal plate of said heat spreader around the border.

8. The heat sink and heat spreader bonding structure as claimed in claim 1, wherein said heat sink comprises a plurality of radially extended radiation fins and a cylindrical center through hole; said heat spreader is a cylindrical member received in the cylindrical center through hole of said heat sink; said first bonding layer and said second bonding layer are bonded between the periphery of the cylindrical center through hole of said heat sink and the periphery of the cylindrical member of said heat spreader.

9. A heat sink and heat spreader bonding structure comprising:
a heat sink made of a first metal material, said first metal material having a first melting point;
a heat spreader made of a second metal material, said second metal material having a second melting point, said first metal material and said second metal material being different and capable of forming an eutectic structure when heated to above their eutectic temperature; and
an intermediate element mounted in between said heat sink and said heat spreader and heated to a specific temperature to form a first bonding layer and a second bonding layer;
wherein said intermediate element comprises at least one top area and at least one bottom area, said at least one top area disposed in contact with said heat sink and comprising at least said second metal material, said at least one bottom area disposed in contact with said heat spreader and comprising at least said first metal material;
wherein said specific temperature is above the eutectic temperature of said first metal material and said second metal material but below said first melting point and said second melting point, such that the atoms of the first metal material of said heat sink and the atoms of the second metal material of the at least one top area of said intermediate element are rearranged to construct an eutectic structure to form said first bonding layer, and the atoms of the second metal material of said heat spreader and the atoms of the first metal material of the at least one bottom area of said intermediate element are rearranged to construct another eutectic structure to form said second bonding layer when heated to said specific temperature.

10. The heat sink and heat spreader bonding structure as claimed in claim 9, wherein said first metal material and said second metal material are different and respectively selected from aluminum and copper.

11. The heat sink and heat spreader bonding structure as claimed in claim 9, wherein said intermediate element is selected from a group of: a foil of the eutectic material of said first metal material and said second metal material, a bi-layer foil having a layer of said first metal material and a layer of said second metal material, a foil of said first metal material coated with a layer of said second metal material on the at least one top area thereof, a foil of said second metal material coated with a layer of said first metal material on the at least one bottom area thereof, a foil of said first metal material coated with a layer of eutectic material formed of said first metal material and said second metal material on the at least one top area thereof, a foil of said second metal material coated with a layer of eutectic material formed of said first metal material and said second metal material on the at least one bottom area thereof, and a layer of coating of eutectic material formed of said first metal material and said second metal material and directly coated on one of said heat sink and said heat spreader.

12. The heat sink and heat spreader bonding structure as claimed in claim 11, wherein each said coating is respectively formed by means of one of the coating techniques including electroplating, evaporation, and sputtering.

13. The heat sink and heat spreader bonding structure as claimed in claim 9, wherein said heat sink comprises a metal plate, which has a top surface and a bottom surface, and a plurality of upright radiation fins upwardly extended from the top surface of the metal plate of said heat sink; said heat spreader comprises a metal plate, which has a top surface; said first bonding layer and said second bonding layer are bonded between the bottom surface of the metal plate of said heat sink and the top surface of the metal plate of said heat spreader.

14. The heat sink and heat spreader bonding structure as claimed in claim 13, wherein at least one flange is formed on at least one of the bottom surface of the metal plate of said heat sink and the top surface of the metal plate of said heat spreader around the border.

15. The heat sink and heat spreader bonding structure as claimed in claim 9, wherein said heat sink comprises a plurality of radially extended radiation fins and a cylindrical center through hole; said heat spreader is a cylindrical member received in the cylindrical center through hole of said heat sink; said first bonding layer and said second bonding layer are bonded between the periphery of the cylindrical center through hole of said heat sink and the periphery of the cylindrical member of said heat spreader.

16. A heat sink and heat spreader bonding structure comprising:
a heat sink made of a first metal material, said first metal material having a first melting point;
a heat spreader made of a second metal material, said second metal material having a second melting point, said first metal material and said second metal material being different and capable of forming an eutectic structure when heated to above their eutectic temperature; and
a bonding layer formed in between said heat sink and said heat spreader upon heating of said heat sink and said heat spreader to a specific temperature;
wherein said specific temperature is above the eutectic temperature of said first metal material and said second metal material but below said first melting point and said second melting point, such that the atoms of the first metal material of said heat sink and the atoms of the second metal material of said heat spreader are rearranged to construct an eutectic structure to form said bonding layer when heated to said specific temperature.

17. The heat sink and heat spreader bonding structure as claimed in claim 16, wherein said first metal material and said second metal material are different and respectively selected from aluminum and copper.

18. The heat sink and heat spreader bonding structure as claimed in claim 16, wherein said heat sink comprises a metal plate, which has a top surface and a bottom surface, and a plurality of upright radiation fins upwardly extended from the top surface of the metal plate of said heat sink; said heat spreader comprises a metal plate, which has a top surface; said bonding layer is bonded between the bottom surface of the metal plate of said heat sink and the top surface of the metal plate of said heat spreader.

19. The heat sink and heat spreader bonding structure as claimed in claim 16, wherein said heat sink comprises a plurality of radially extended radiation fins and a cylindrical center through hole; said heat spreader is a cylindrical member received in the cylindrical center through hole of said heat sink; said bonding layer is bonded between the periphery of the cylindrical center through hole of said heat sink and the periphery of the cylindrical member of said heat spreader.
